(19) United States
(12) Patent Application Publication
(10) Pub. No.: US 2013/0090242 A1
(43) Pub. Date: Apr. 11, 2013

(54) Techniques for Sub-Cooling in a Superconducting System

(71) Applicants: James D. Strassner, Austin, TX (US); Gregory Citver, Danvers, MA (US); Frank Sinclair, Quincy, MA (US)

(72) Inventors: James D. Strassner, Austin, TX (US); Gregory Citver, Danvers, MA (US); Frank Sinclair, Quincy, MA (US)

(73) Assignee: Varian Semiconductor Equipment Associates, Inc., Gloucester, MA (US)

(21) Appl. No.: 13/253,652

(22) Filed: Oct. 5, 2011

(51) Int. Cl. H01L 39/02; H01F 6/00; F25D 31/00; H01F 6/04; H02H 7/00

(52) U.S. Cl. 505/163; 505/150; 505/211; 361/19; 335/216; 62/62

(57) ABSTRACT

Techniques for sub-cooling in a superconducting (SC) system is disclosed. The techniques may be realized as a method and superconducting (SC) system comprising at least one insulated enclosure configured to enclose at least a first fluid or gas and a second fluid or gas, and at least one superconducting circuit within the at least one insulated enclosure. The superconducting (SC) system may be sub-cooled using at least the first fluid or gas.

### FIELD OF THE DISCLOSURE

The present disclosure relates generally to sub-cooling and, more particularly, to techniques for sub-cooling in a superconducting (SC) system.

### BACKGROUND OF THE DISCLOSURE

In electric power transmission and distribution networks, fault current conditions may occur. A fault current condition is an abrupt surge in the current flowing through the network caused by a fault or a short circuit in the network. Causes of a fault may include lightning striking the network, and downing and grounding of transmission power lines due to severe weather or falling trees. When a fault occurs, a large load appears instantaneously. In response, the network delivers a large amount of current (i.e., overcurrent) to this load or, in the case, the fault. This surge or fault current condition is undesirable and may damage the network or equipment connected to the network. In particular, the network and the equipment connected thereto may burn or, in some cases, explode.

One system used to protect power equipment from damage caused by a fault current is a circuit breaker. When a fault current is detected, the circuit breaker mechanically opens the circuit and disrupts overcurrent from flowing. Because a circuit breaker typically take 3 to 6 power cycles (up to 0.1 seconds) to be triggered, various network components, such as transmission lines, transformers, and switchgear, may still be damaged.

Another system to limit a fault current and to protect power equipment from damage caused by a fault current is a superconducting fault current limiter (SCFCL) system. Generally, an SCFCL system comprises a superconducting circuit that exhibits almost zero resistivity below a critical temperature level T_{C}, a critical magnetic field level H_{C}, and a critical current level I_{C}. If at least one of these critical level conditions is exceeded, the circuit quenches and exhibits resistivity.

During normal operation, the superconducting circuit of the SCFCL system is maintained below the critical level conditions of T_{C}, H_{C}, and I_{C}. During a fault, one or more of the aforementioned critical level conditions is exceeded. Instantaneously, the superconducting circuit in the SCFCL system is quenched and resistance surges, which in turn limits transmission of the fault current and protects the network and associated equipment from the overload. Following some time delay and after the fault current is cleared, the superconducting circuit returns to normal operation wherein none of the critical level conditions are exceeded and current is again transmitted through the network and the SCFCL system.

The temperature of the SCFCL system may be maintained at a desired temperature range using an electrical cooling system, which typically comprises a heat exchanger. However, heat exchangers are expensive, cumbersome, and increase complexity of the SCFCL system.

Accordingly, in view of the foregoing, it may be understood that there may be significant problems and shortcomings associated with current technologies for sub-cooling.

### SUMMARY OF THE DISCLOSURE

Techniques for sub-cooling in a superconducting (SC) system are disclosed. In one particular exemplary embodiment, the techniques may be realized as a superconducting (SC) system comprising at least one insulated enclosure configured to enclose at least a first fluid or gas and a second fluid or gas, and at least one superconducting circuit within the at least one insulated enclosure. The superconducting (SC) system may be sub-cooled using at least the first fluid or gas.

In accordance with other aspects of this particular embodiment, the first fluid or gas may be liquid nitrogen and the second fluid or gas may be helium gas.

In accordance with further aspects of this particular embodiment, the second fluid or gas may have a different boiling point and a different condensation temperature compared to the first fluid or gas.

In accordance with additional aspects of this particular embodiment, the second fluid or gas may have a lower boiling point and a lower condensation temperature than the first fluid or gas.

In accordance with other aspects of this particular embodiment, the second fluid or gas may be disposed above the first fluid or gas in the at least one insulated enclosure.

In accordance with further aspects of this particular embodiment, the superconducting (SC) system may further comprise a duct coupled to a source tank containing the second fluid or gas, where the second fluid or gas may enter the at least one insulated enclosure via the duct.

In accordance with additional aspects of this particular embodiment, the second fluid or gas may be configured to be at 1 atmosphere in the at least one insulated enclosure and may serve as a pressure regulator for the superconducting (SC) system.

In accordance with other aspects of this particular embodiment, the superconducting (SC) system may further comprise a cryo-cooler system comprising at least one cryo-cooler coupled to at least one water chiller.

In accordance with further aspects of this particular embodiment, the cryo-cooler system may cool the first fluid or gas circulated from the at least one insulated enclosure.

In accordance with additional aspects of this particular embodiment, the superconducting (SC) system may further comprise a pump system having at least one pump configured to regulate pressure of the first fluid or gas from the cryo-cooler system to the at least one insulated enclosure.

In accordance with other aspects of this particular embodiment, the superconducting (SC) system may be a superconducting fault current limiter (SCFCL) system, a superconducting (SC) magnet system, or a superconducting (SC) storage system.

In another particular embodiment, the technique(s) may be realized as a method for sub-cooling a superconducting (SC) system. The method may comprise providing a first fluid or gas to at least one insulated enclosure. The method may also comprise providing a second fluid or gas to the at least one insulated enclosure. The at least one superconducting circuit may be within the at least one insulated enclosure. The first fluid or gas and the second-fluid or gas may sub-cool the superconducting (SC) system.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 depicts a superconducting fault current limiter (SCFCL) system using two cooling fluids according to an embodiment of the present disclosure.

FIG. 2 depicts a series of superconducting fault current limiter (SCFCL) systems according to an embodiment of the present disclosure.

FIG. 3 depicts an overall architecture of a superconducting (SC) system coupled to a cooler system and pump system according to an embodiment of the present disclosure.

### DETAILED DESCRIPTION OF EXEMPLARY EMBODIMENTS

Embodiments of the present disclosure provide techniques for sub-cooling in a superconducting (SC) system.

A superconducting fault current limiter (SCFCL) system may comprise an enclosure electrically decoupled from ground, such that the enclosure is electrically isolated from a ground potential. In some embodiments, the enclosure may be grounded. The SCFCL system may also have first and second terminals, electrically connected to one or more current carrying lines, and a first superconducting circuit contained within the enclosure, wherein the first superconducting circuit may be electrically connected to the first and second terminals.

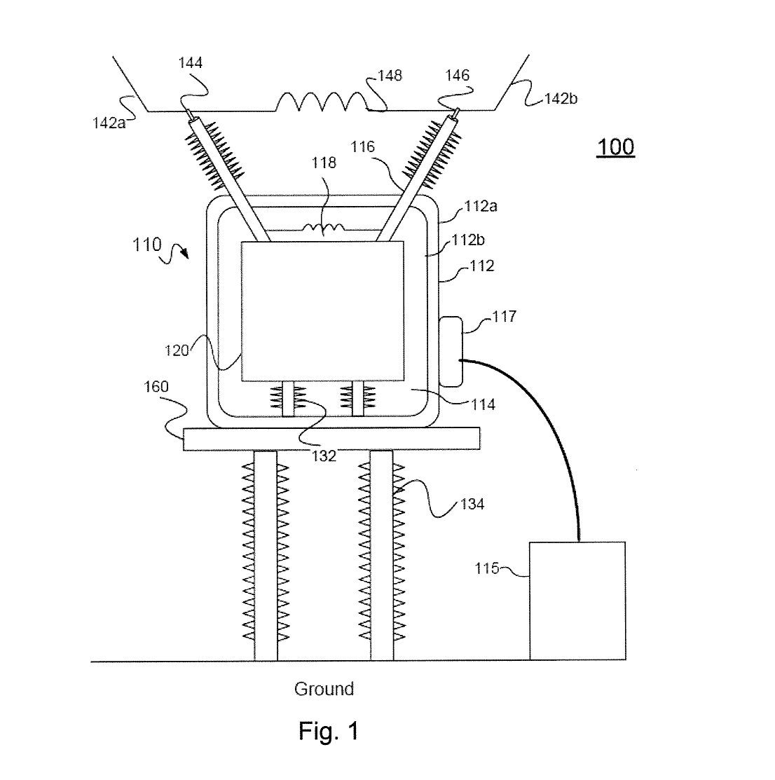

Referring to FIG. 1, there is shown a superconducting fault current limiter (SCFCL) system 100 using current leads according to an embodiment of the present disclosure. The SCFCL system 100 may comprise one or more modules 110. For the purposes of clarity and simplicity, the description of SCFCL system 100 will be limited to one single phase module 110 although various other embodiments using more than one phase module may be contemplated in accordance with the present disclosure.

The phase module 110 of SCFCL system 100 may comprise an enclosure or tank 112 defining a chamber therein. In one embodiment, the enclosure or tank 112 may be thermally insulated. In other embodiments, the enclosure or tank 112 may be electrically insulated. The enclosure or tank 112 may be made from a variety of materials, such as fiberglass or other dielectric materials. In other embodiments, the enclosure or tank 112 may be made of a conductive material, such as metal (e.g., copper, aluminum, or other metal). The enclosure of tank 112 may also comprise an outer layer 112a and an inner layer 112b. An insulating medium (e.g., a thermal and/or electrically insulating medium) may be interposed between the outer layer 112a and the inner layer 112b. In some embodiments, the enclosure or tank 112 may or may not be connected to earth ground. In the configuration depicted in FIG. 1, the enclosure or tank 112 is not connected to earth ground, and thus may be referred to as a floating tank configuration.

Within the enclosure or tank 112, there may be one or more fault current limiting units 120, which, for the purpose of clarity and simplicity, are shown as a block. The module 110 may also comprise one or more electrical bushings 116. Distal ends of the bushings 116 may be coupled to transmission network current lines 142a and 142b via terminals 144 and 146, respectively. This configuration may allow the module 110 to be coupled to a transmission network (not shown). The current lines 142a and 142b may be transmission lines to transmit power from one location to another (e.g., current source to current end users), or power or current distribution lines.

Meanwhile, the outer layer 112a may be used to insulate the enclosure or tank 112 from inner conductive material, thereby allowing the enclosure or tank 112 and the terminals 144 and 146 to be at different electrical potentials. In some embodiments, the module 110 may comprise an internal shunt reactor 118 or an external shunt reactor 148, or both, to connect the conductive material contained in the electrical bushings 116.

Several insulated supports may be used to insulate various voltages from one another. For example, insulated supports 132 within the enclosure or tank 112 may be used to isolate the voltage of the module 120 from the enclosure or tank 112. Additional supports 134 may be used to isolate a platform 160 and the components resting thereon from ground. Other various embodiments may also be provided.

The temperature of the fault current limiting unit 120 may be maintained at a desired temperature range using coolant 114 in the enclosure or tank 112. In some embodiments, the fault current limiting unit 120 may be cooled and maintained at a low temperature range, for example, at or around ˜77° K. According to embodiments of the present disclosure, the coolant 114 may include at least a first fluid or gas and a second fluid or gas. For example, the first fluid or gas may be liquid nitrogen (LN₂) or other cryogenic fluid or gas. The second fluid or gas may be helium (He) gas or other fluid or gas having a condensation temperature that is lower than the first fluid or gas. In some embodiments, the second fluid or gas may be disposed above the first fluid or gas within the enclosure or tank 112.

As described above, using a heat exchanger in an electrical cooling system may be expensive, cumbersome, and increase complexity of an overall architecture of the SCFCL system. As a result, sub-cooling an SCFCL system, or other type of superconducting (SC) system, without using a heat exchanger may provide a simple and cost-effective solution.

Placing helium gas above the liquid nitrogen, for example, in the enclosure or tank 112 may allow helium gas to serve as a pressure regulator. Helium gas and liquid nitrogen have different boiling points and different condensation temperatures. Liquid nitrogen may boil when vapor pressure is greater than the ambient pressure. To prevent liquid nitrogen from boiling, helium gas may be introduced at 1 atm to a single SCFCL system or to a plurality of SCFCL systems (“cryostat”). When this is achieved, the SCFCL system may be sub-cooled below the boiling point and condensation temperature of the liquid nitrogen without causing excessive arcing between and among the different components of the SCFCL system.

It should be appreciated that when helium gas, with a lower boiling and condensation temperature, is placed above liquid nitrogen, the helium gas may not condense even if the SCFCL system is sub-cooled. In addition, it should be appreciated that helium gas may be a superior electrical insulator as well. As a result, providing helium gas on top of liquid nitrogen may further prevent arcing between and among the components in the SCFCL system.

Moreover, helium gas may allow the SCFCL system to be maintained at sub-cooled conditions and extend the lifetime of superconductor tape. Superconductor tape may be used in superconducting systems and may be made of a variety of materials, such as niobium-titanium, yttrium barium copper oxide (YBCO), gadolinium barium copper oxide (GBCO), or other superconductive materials. In general, superconductor tape may be costly to construct and may lose effectiveness in unregulated sub-cooled environments. Thus, when an SCFCL system is maintained at a sub-cooled environment, the condition and lifetime of the superconductor tape may also be extended and preserved, resulting in overall improved performance of the SCFCL system.

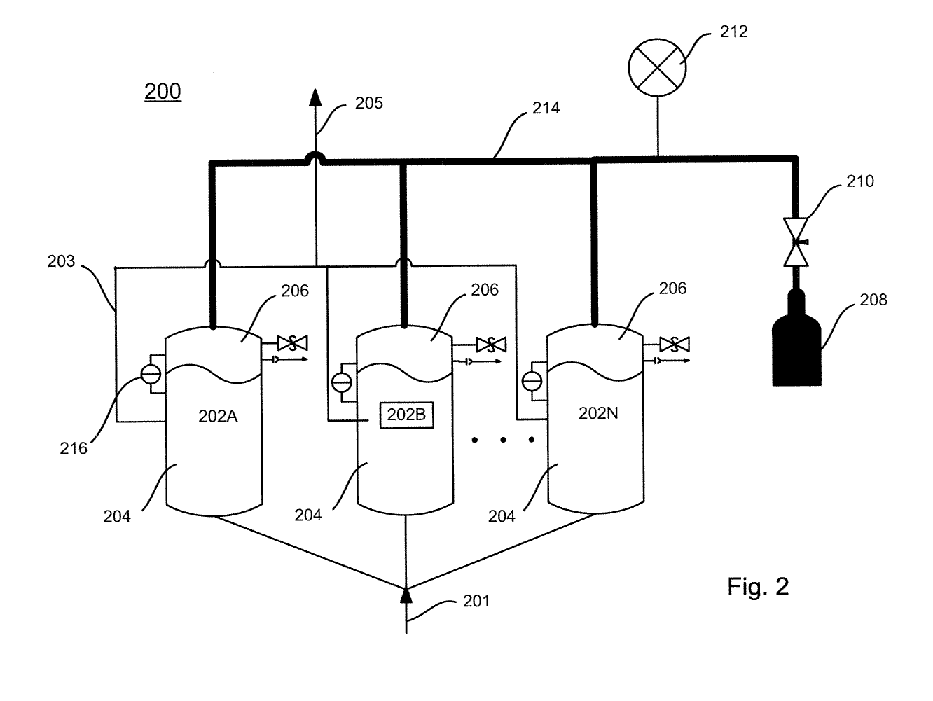

FIG. 2 depicts a series 200 of superconducting fault current limiter (SCFCL) systems according to an embodiment of the present disclosure. Referring to FIG. 2, there may be multiple superconducting fault current limiter (SCFCL) systems 202A, 202B, and 202N, collectively referred to as a “cryostat.” The SCFCL systems may be coupled to each other in a series or other form of coupling. It should be appreciated that although three SCFCL systems are shown in the cryostat arrangement, there may be N number of SCFCL systems, where N is an integer that may be greater or lesser than three.

As described above with reference to FIG. 1, each of the SCFCL systems of FIG. 2 may comprise a first fluid or gas 204 (e.g., liquid nitrogen or other cryogen) and a second fluid or gas 206 (e.g., helium gas or other similar fluid or gas). A pressurized helium tank 208 may be coupled to a helium gas regulator 210, which in turn may be used to control and provide helium gas to each of the SCFCL systems via a duct 214. Using this configuration, helium gas may be disposed above the liquid nitrogen 204, as described above. In some embodiments, a pressure gauge 212 may also be provided to assist in measuring and controlling the pressure of helium gas provided to the SCFCL systems 202.

The series 200 of SCFCL systems 202 may also comprises a line for transmission and flow of the first fluid or gas (e.g., liquid nitrogen). For example, liquid nitrogen may enter the series 200 of SCFCL systems 202 via input line 201, may be distributed among the SCFCL systems 202 via line 203, and may exit the SCFCL systems 202 via output line 205. In some embodiments, each SCFCL system 202 may also comprise a sensor 216 to measure and/or monitor levels of the first fluid or gas and/or the second fluid or gas. Other various embodiments may also be provided.

The capability to pressurize a cryostat with helium gas enables liquid nitrogen sub-cooling. For example, helium gas may not liquefy when temperatures drop below an equilibrium temperature for liquid nitrogen at a particular pressure. Therefore, pressure may not drop in the cryostat as temperature of liquid nitrogen decreases.

When used in conjunction with a cryo-cooler system and a pump system, pressurized liquid nitrogen may circulate through the cryo-cooler, resulting in a drop in liquid nitrogen temperature while maintaining a desired pressure with helium gas. As a result, the cryo-cooler system may cool liquid nitrogen and helium gas may regulate pressure, thus obtaining sub-cooling.

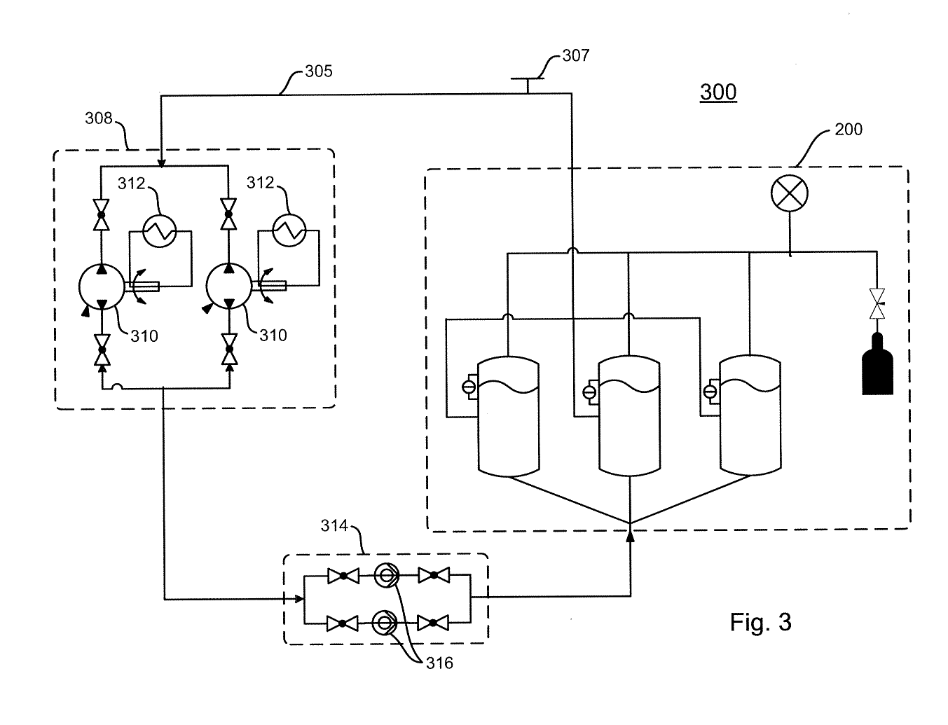

FIG. 3 depicts an overall architecture 300 of a superconducting (SC) system coupled to a cooler system and pump system according to an embodiment of the present disclosure. As shown in the FIG. 3, the series 200 of SCFCL systems 202 from FIG. 2 may be coupled via line 305 to a cryo-cooler system 308 and a pump system 314. Liquid nitrogen may circulate via line 305 from the cryostat 200 to the cryo-cooler system 308. In some embodiments, there may be a port 307 for inputting or outputting a first fluid or gas.

The cryo-cooler system 308 may comprise one or more cryo-coolers 310. In some embodiments, each of the cryo-coolers 310 may be coupled to a water chiller 312 or other similar device. The cryo-cooler system 308 may be configured to remove heat from the liquid nitrogen. The cooled liquid nitrogen may then be pumped back to the cryostat 200, which may be pressurized with helium gas, as described above. The SCFCL systems 202 may then reject heat to the sub-cooled liquid nitrogen and this heated liquid nitrogen may then travel back through line 305 to the cryo-cooler system 308, where the cycle is repeated.

The pump system 314 may comprise one or more pumps 316 configured to control and regulate pressure. It should be appreciated that the cryo-cooler system 308 may operate in less than 1 atm. As a result, a pressure gradient may develop in the liquid nitrogen at the pump system 314. Accordingly, the pump system 314 may be configured to adequately pressurize the liquid nitrogen before the liquid nitrogen is circulated back into the cryostat 200 from the cryo-cooler system 308.

It should be appreciated that while only two cryo-coolers 310 and two water chillers 312 are depicted in the cryo-cooler system 308, and only two pumps 316 are depicted in the pump system 314, a greater or lesser number of cryo-coolers, water chillers, and/or pumps may be provided.

Using the above-described circulating system, sub-cooling may be achieved. Without the use of helium gas to regulate pressure, an SCFCL system may move towards equilibrium which may cause a drop in pressure as temperature of liquid nitrogen decreases.

Implementing the overall architecture 300 of FIG. 3 may also help resolve a variety of problems. For example, liquid nitrogen at equilibrium (1 atm, 77° K) may create multiple issues for an SCFCL. Also, when an SCFCL system is subjected to high current, high voltage faults, and several issues may occur.

First, there may be an appearance of undesirable bubbles. Bubbles may appear at an interface between superconductor tape and liquid nitrogen. Bubbles may prevent an SCFCL system from returning to a superconducting state by delaying heat transfer from the superconductor tape to the liquid nitrogen. Bubbles may also increase internal stresses on the superconductor tape as they expand between layers of the superconductor tape. Bubbles may further create large pressure spikes in a cryostat, thereby causing structural damage and creating unstable thermodynamic conditions for the liquid nitrogen.

Second, a critical current (I_{c}) may be reduced at higher temperature liquid nitrogen (77° K), which may significantly increase a quantity of superconductor tape required, as compared to an SCFCL system which uses lower temperature liquid nitrogen.

Third, dielectric properties of liquid nitrogen may be lower at higher temperature (77° K), which may significantly increase a separation distance required to prevent arcing, as compared to an SCFCL system which uses lower temperature liquid nitrogen. Fourth, forces on superconductor tape may be higher on higher temperature liquid nitrogen (77° K), as compared to an SCFCL system which uses lower temperature liquid nitrogen.

Sub-cooling using the aforementioned embodiments may resolve and/or minimize each of these undesirable issues. By sub-cooling a cryostat as described above, overheating or burning of superconductor tape by a fault current during a fault condition may be reduced or eliminated. Maintaining an SCFCL system tank at a sub-cooled condition may also extend the lifetime of superconductor tape. An SCFCL system tank with only one type of coolant maintained at a sub-cooled condition may not operate optimally. For example, if an SCFCL system containing only liquid nitrogen is sub-cooled, pressure above liquid nitrogen may be lowered, as nitrogen gas condenses into liquid nitrogen, and an area with low pressure may be created. This low pressure area may serve as a poor electrical insulator and arcing between/among components in this area (e.g. current leads) may occur. As a result, embodiments of the present disclosure may provide techniques for sub-cooling in a superconducting (SC) system with advantageous effects not otherwise achievable in traditional systems using a costly and cumbersome heat exchanger. While embodiments for sub-cooling are described above without use of a heat exchanger, it should be appreciated that embodiments for sub-cooling may be achieved with or without a heat exchanger.

It should be appreciated that while the above embodiments have been described primarily with regard to liquid nitrogen as the first fluid or gas and helium as the second fluid or gas, other various fluids or gases may also be provided. These may include, but not limited to, helium, argon, carbon dioxide, and isobutane as the first fluid or gas, and also neon as the second fluid or gas.

It should also be appreciated that while embodiments of the present disclosure are directed to applications in a superconducting fault current limiter (SCFCL) system, other various applications and implementations may also be contemplated, such as superconductive (SC) magnets, superconductive energy storage, and other superconducting applications or applications using coolants.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A superconducting (SC) system comprising:
at least one insulated enclosure configured to enclose at least a first fluid or gas and a second fluid or gas; and
at least one superconducting circuit within the at least one insulated enclosure;
wherein the first superconducting (SC) system is sub-cooled using at least the first fluid or gas.

2. The superconducting (SC) system of claim 1, wherein the first fluid or gas is liquid nitrogen and the second fluid or gas is helium gas.

3. The superconducting (SC) system of claim 1, wherein the second fluid or gas has a different boiling point and a different condensation temperature compared to the first fluid or gas.

4. The superconducting (SC) system of claim 4, wherein the second fluid or gas has a lower boiling point and a lower condensation temperature than the first fluid or gas.

5. The superconducting (SC) system of claim 1, wherein the second fluid or gas is disposed above the first fluid or gas in the at least one insulated enclosure.

6. The superconducting (SC) system of claim 1, further comprising a duct coupled to a source tank containing the second fluid or gas, wherein the second fluid or gas enters the at least one insulated enclosure via the duct.

7. The superconducting (SC) system of claim 1, wherein the second fluid or gas is configured to be at 1 atmosphere in the at least one insulated enclosure and serves as a pressure regulator for the superconducting (SC) system.

8. The superconducting (SC) system of claim 1, further comprising a cryo-cooler system comprising at least one cryo-cooler coupled to at least one water chiller.

9. The superconducting (SC) system of claim 9, wherein the cryo-cooler system cools the first fluid or gas circulated from the at least one insulated enclosure.

10. The superconducting (SC) system of claim 9, further comprising a pump system comprising at least one pump configured to regulate pressure of the first fluid or gas from the cryo-cooler system to the at least one insulated enclosure.

11. The superconducting (SC) system of claim 1, wherein the superconducting (SC) system comprises at least one of a superconducting fault current limiter (SCFCL) system, a superconducting (SC) magnet system, and a superconducting (SC) storage system.

12. A method for sub-cooling a superconducting (SC) system, the method comprising:
providing a first fluid or gas to at least one insulated enclosure; and
providing a second fluid or gas to the at least one insulated enclosure;
wherein at least one superconducting circuit is within the at least one insulated enclosure, and wherein the first fluid or gas and the second-fluid or gas sub-cool the superconducting (SC) system.

13. The method of claim 12, wherein the first fluid or gas is liquid nitrogen and the second fluid or gas is helium gas.

14. The method of claim 12, wherein the second fluid or gas has a different boiling point and a different condensation temperature compared to the first fluid or gas.

15. The method of claim 14, wherein the second fluid or gas has a lower boiling point and a lower condensation temperature than the first fluid or gas.

16. The method of claim 12, wherein the second fluid or gas is disposed above the first fluid or gas in the at least one insulated enclosure.

17. The method of claim 12, further comprising setting the second fluid or gas to be at 1 atmosphere in the at least one insulated enclosure, wherein the second fluid or gas is configured to serve as a pressure regulator for the superconducting (SC) system.

18. The method system of claim 12, further comprising cooling the first fluid or gas circulated from the at least one insulated enclosure using a cryo-cooler system.

19. The method of claim 18, wherein the cryo-cooler system comprises at least one cryo-cooler coupled to at least one water chiller.

20. The method of claim 18, further comprising a pump system comprising at least one pump configured to regulate pressure of the first fluid or gas from the cryo-cooler system to the at least one insulated enclosure.

21. The method of claim 12, wherein the superconducting (SC) system comprises at least one of a superconducting fault current limiter (SCFCL) system, a superconducting (SC) magnet system, and a superconducting (SC) storage system.
